(19) United States
(12) Patent Application Publication
(10) Pub. No.: US 2005/0110017 A1
(43) Pub. Date: May 26, 2005

(54) TFT modulating threshold voltage and flat panel display having the same

(76) Inventors: Myeong-Seob So, Cheonan-si (KR); Byoung-Deog Choi, Seoul (KR)

Correspondence Address: MCGUIREWOODS, LLP, 1750 TYSONS BLVD, SUITE 1800, MCLEAN, VA, 22102, US

(21) Appl. No.: 10/992,086

(22) Filed: Nov. 19, 2004

(30) Foreign Application Priority Data
Nov. 21, 2003 (KR) 2003-83050

(51) Int. Cl. H01L 27/108

(52) U.S. Cl. 257/69

(57) ABSTRACT

The invention is directed to a thin film transistor (TFT) that modulates a threshold voltage in a simple manner. In one embodiment a TFT of the present invention also reduces a leakage current in an off state, and guarantees a sufficient threshold voltage margin and a flat panel display having the same are provided. The TFT includes a semiconductor thin film having a channel area and n-type or p-type impurity-doped source and drain areas. A gate electrode is formed in a position corresponding to the channel area. The TFT further includes gate insulating layer, which insulates the semiconductor thin film and the gate electrode. Source and drain electrodes are connected to each of the source and drain areas of the semiconductor thin film. In a TFT configured in this manner, a threshold voltage is modulated by changing a work function difference between the gate electrode and the semiconductor thin film.

### CROSS-REFERENCE TO RELATED APPLICATIONS

This application claims priority of Korean Patent Application No. 2003-83050, filed on Nov. 21, 2003, in the Korean Intellectual Property Office, the disclosure of which is in its entirety incorporated herein by reference.

### BACKGROUND OF THE INVENTION

1. Field of the Invention

The present invention relates to thin film transistors (TFTs) generally, and more particularly, to an improved TFT that modulates a threshold voltage and a flat panel display having the same.

2. Description of the Related Art

A thin film transistor (TFT) like a metal oxide semiconductor field effect transistor (MOSFET) is a device which turns a channel on/off in response to a signal applied to a gate electrode. TFTs are formed by doping p-type or n-type impurities in source and drain areas. The type of doped impurities may be used to clarify a thin film transistor (TFT) as one of a PMOS TFT or a NMOS TFT. Additionally, complementary metal oxide silicon (CMOS) technology may be used to connect PMOS TFTs and NMOS TFTs together. In the PMOS TFT, a hole is used as a carrier composing a channel. In the NMOS TFT, an electron is used as the carrier composing the channel. These TFTs are widely used in a variety of electronic devices including flat panel displays.

In a conventional TFT, a doping amount, the size of a channel, or a doping depth is adjusted so that a threshold voltage is modulated. However, this method of modulating the threshold voltage may adversely adjust the dimensions of the TFT, or complicate the processes used to manufacture the TFT.

The previously described CMOS technology connects a PMOS TFT and a NMOS TFT together, and may have an inverting function. CMOS circuits are widely used because they improve the efficiency of the TFT and increase its operating speed.

Additionally, the CMOS circuit helps reduce the overall size of an electronic device, which improves integration and increases voltage characteristics and operating speed.

However, CMOS circuits used in active matrix-type organic electroluminescent (EL) devices require a sufficient threshold voltage Vₜₕ to reduce a leakage current in an off state and achieve sufficient operating characteristics in an on state.

FIG. 1 shows a gate voltage V_{g} of a conventional CMOS circuit used in an active matrix-type organic EL device versus a drain current I_{d} of a conventional PMOS TFT and a conventional NMOS TFT. A metallic electrode is used as a gate electrode of the PMOS TFT and the NMOS TFT.

In the CMOS circuit, as shown in FIG. 1, a threshold voltage margin (which is a difference between a threshold voltage Vₜₕ of the PMOS TFT and a threshold voltage V_{th′} of the NMOS TFT) is very small. This is meaningful because, in the conventional CMOS circuit, if the threshold voltage margin is insufficient, the circuit's normal operation is hindered, and power loss occurs. In addition, characteristics in an off state, in which a voltage is not applied to a gate electrode, are lowered.

### SUMMARY OF THE INVENTION

The present invention provides an improved thin film transistor (TFT) that modulates a threshold voltage in a simple manner and a flat panel display having the same. A TFT of the margin present invention also provides a TFT having a sufficient threshold voltage margin and improves characteristics in an off state. Additionally, a flat panel display having such TFT is also provided.

According to one embodiment of the present invention, there is provided a thin film transistor (TFT) that includes a semiconductor thin film having a channel area and n-type or p-type impurity-doped source and drain areas. The TFT also includes a gate electrode formed in a position corresponding to the channel area; a gate insulating layer, which insulates the semiconductor thin film and the gate electrode. Source and drain electrodes are connected to each of the source and drain areas of the semiconductor thin film. The TFT is configures to modulate a threshold voltage by changing a work function difference between the gate electrode and the semiconductor thin film.

For example, the threshold voltage may be modulated by changing the work function difference between the gate electrode and the semiconductor thin film within the range of a half of a difference of a conduction band and a balance band of either the gate electrode or the semiconductor thin film.

The semiconductor thin film and the gate electrode may be formed of polysilicon n-type or p-type impurities may be doped in both the source and drain are as well as gate electrode. Alternatively, the gate electrode may be doped with impurities different from the impurities doped in the source and drain areas.

According to another aspect of the present invention, there is provided a CMOS circuit that includes both a NMOS TFT and a PMOS TFT. The NMOS thin film transistor may include (i) a first semiconductor thin film having a channel area and n-type impurity-doped source and drain areas, (ii) a first gate electrode formed in a position corresponding to the channel area of the first semiconductor thin film, (iii) a first gate insulating layer, which insulates the first semiconductor thin film and the first gate electrode, and (iv) first source and drain electrodes, which are connected to each of the first source and drain areas of the first semiconductor thin film. The PMOS thin film transistor may include (i) a second semiconductor thin film having a channel area and p-type impurity-doped source and drain areas, (ii) a second gate electrode formed in a position corresponding to the channel area of the second semiconductor thin film, (iii) a second gate insulating layer, which insulates the second semiconductor thin film and the second gate electrode, and (iv) second source and drain electrodes, which are connected to each of the second source and drain areas of the second semiconductor thin film. In one embodiment of the CMOS circuit, the threshold voltage of the NMOS thin film transistor is modulated by changing a work function difference between the first is gate electrode and the first semiconductor thin film; and the threshold voltage of the PMOS thin film transistor is modulated by changing a work function difference between the second gate electrode and the second semiconductor thin film.

Illustratively, the threshold voltage of the NMOS thin film transistor may be modulated by changing the work function difference between the first gate electrode and the first semiconductor thin film within the range of a half of a difference of a conduction band and a balance band of the first gate electrode or the first semiconductor thin film.

Additionally, the threshold voltage of the PMOS thin film transistor may be modulated by changing the work function difference between the second gate electrode and the second semiconductor thin film within the range of a half of a difference of a conduction band and a balance band of the second gate electrode or the second semiconductor thin film.

The first and second semiconductor thin films and the first and second gate electrodes may be formed of polysilicon p-type impurities may be doped in the first gate electrode n-type impurities may be doped in the second gate electrode.

### BRIEF DESCRIPTION OF THE DRAWINGS

The above and other aspects and advantages of the present invention will become more apparent by describing in detail exemplary embodiments thereof with reference to the attached drawings.

FIG. 1 shows a gate voltage V_{g} of a conventional CMOS circuit used in an active matrix-type organic EL device versus a drain current I_{d} of a conventional PMOS TFT and a conventional NMOS TFT.

FIG. 2 is a cross-sectional view of a thin film transistor (TFT) according to an

FIG. 3 shows an energy band diagram of a gate electrode-gate insulating layer-semiconductor thin film of an NMOS TFT according to the present invention.

FIG. 4 is a graph of a gate voltage V_{g} versus a drain current I_{d} of the NMOS TFT shown in FIG. 3.

FIG. 5 shows an energy band diagram of a gate electrode-gate insulating layer-semiconductor thin film of a PMOS TFT according to the present invention.

FIG. 6 is a graph of a gate voltage V_{g} versus a drain current I_{d} of the PMOS TFT shown in FIG. 5.

FIG. 7 is a cross-sectional view of a CMOS circuit according to an embodiment of the present invention.

FIG. 8 is a graph of a gate voltage V_{g} versus a drain current I_{d} of the CMOS TFT shown in FIG. 7.

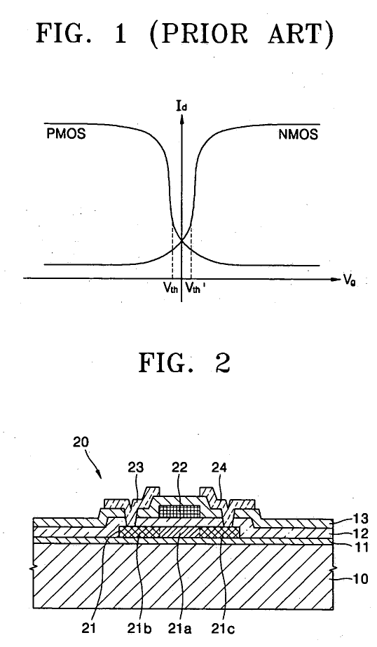

### DETAILED DESCRIPTION OF THE INVENTION

Exemplary embodiments of the present invention will be described with reference to the accompanying drawings.

FIG. 2 shows a thin film transistor (TFT) according to an embodiment of the present invention. Referring to FIG. 2, a thin film transistor (TFT) 20 is formed on a substrate 10. A buffer layer 11 is formed on the substrate 10. A semiconductor thin film 21 is formed on the buffer layer 11, and a gate insulating layer 12 is formed to cover the semiconductor thin film 21. A gate electrode 22 is formed on the gate insulating layer 12, and an interlevel dielectric (ILD) layer 13 is formed to cover the gate electrode 22. After a via hole is perforated in the ILD is layer 13 and the gate insulating layer 12, a source electrode 23 and a drain electrode 24 are formed to contact the semiconductor thin film 21. The structure of the TFT 20 is not necessarily limited to this, and the TFT 20 may have diverse structures.

The semiconductor thin film 21 is formed of polysilicon and comprises impurity-doped source area 21b and drain area 21c and a channel area 21a which connects the source area 21b and the drain area 21c. The TFT 20 may be classified into a PMOS TFT and an NMOS TFT depending on whether p-type or n-type impurities are doped in the source and drain areas 21b and 21c. The source electrode 23 contacts the source area 21b of the semiconductor thin film 21, and the drain electrode 24 contacts the drain area 21c of the semiconductor thin film 21.

Meanwhile, in the TFT, a value of a threshold voltage Vₜₕ is given by Equation 1.

$$Vth = Φms + 2 Φf + \frac{1}{Cox} \sqrt{4 qKsεoxΦfNA} - \frac{qDi}{Cox} \qquad ( 1 )$$

φ ms is a value obtained by subtracting a work function of the semiconductor thin film 21 from a work function of the gate electrode 22. As equation 1 illustrates, threshold voltage of the TFT may be adjusted by varying the difference between the work functions. In the prior art, however, the work function difference was not modulated as a variable because the difference was determined by a material used in forming the semiconductor thin film 21 and a material used in forming the gate electrode 22. However, as further explained below, the present invention modulates a threshold voltage of a TFT by changing the work function difference. To this end, according to an exemplary embodiment of the present invention, the gate electrode 22 is formed of polysilicon, and n-type or p-type impurities are doped in the gate electrode 22.

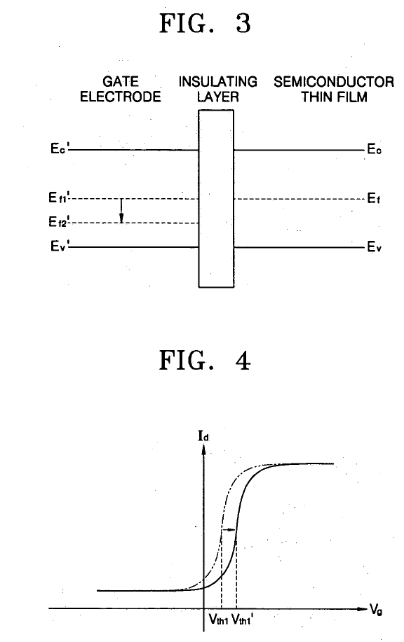

FIG. 3 shows an energy band diagram of a gate electrode-gate insulating layer-semiconductor thin film when p-type impurities are doped in a gate electrode formed of polysilicon of an NMOS TFT. As shown in FIG. 3, when p-type impurities are doped in the gate electrode 22, a Fermi level is reduced from E_{f1}′ to E_{f2}′. Thus, φ ms which is the work function difference obtained by subtracting the work function of the semiconductor thin film 21 from the work function of the gate electrode 22, is increased by a (+) value which corresponds to a difference between E_{f} and E_{f2}′. As a result, as shown in Equation 1 and FIG. 4, the threshold voltage Vₜₕ is increased from Vₜₕ₁ to Vₜₕ₁′, and the graph of a gate voltage V_{g} versus a drain current I_{d} is shifted to the right side.

The threshold voltage of the NMOS TFT may be modulated by modulating the work function difference between the gate electrode and the semiconductor thin film within a half band gap. That is, the threshold voltage of the NMOS TFT may be modulated by changing the work function difference between the gate electrode and the semiconductor thin film within the range of a half ((E_{c}′−Eᵥ′)/2) of a difference between a conduction band E_{c}′ and a balance band Eᵥ′ of the gate electrode or within the range of a half ((E_{c}′−Eᵥ)/2) of a difference between a conduction band E_{c} and a balance band Eᵥ of the semiconductor thin film.

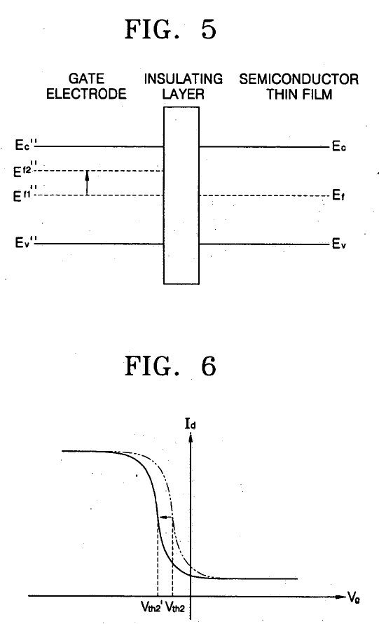

FIG. 5 shows an energy band diagram of a gate electrode-gate insulating layer-semiconductor thin film when n-type impurities are doped in a gate electrode formed of polysilicon of a PMOS TFT. As shown in FIG. 5, when n-type impurities are doped in the gate electrode 22, a Fermi level is increased from E_{f1}″ to E_{f2}″, and φ ms which is the work function difference obtained by subtracting the work function of the semiconductor thin film 21 from the work function of the gate electrode 22, is reduced by a (−) value which corresponds to a difference between E_{f} and E_{f2}″. As a result, as shown in Equation 1 and FIG. 6, the threshold voltage Vₜₕ is increased from Vₜₕ₂ to Vₜₕ₂′, and the graph of a gate voltage V_{g} versus a drain current I_{d} is shifted to the left side.

As demonstrated above, the threshold voltage of the PMOS TFT may be changed by modulating the work function difference between the gate electrode and the semiconductor thin film within a half band gap. That is, the threshold voltage of the PMOS TFT may be modulated by changing the work function difference between the gate electrode and the semiconductor thin film within the range of a half ((E_{c}″−Eᵥ″)/2) of a difference between a conduction band E_{c}″ and a balance band Eᵥ″ of the gate electrode or within the range of a half ((E_{c}−Eᵥ)/2) of a difference between a conduction band E_{c} and a balance band Eᵥ of the semiconductor thin film.

As described above, the work function difference between the semiconductor thin film and the gate electrode is modulated so that the threshold voltage Vₜₕ is modulated in a simple manner. In addition, as shown in FIGS. 4 and 6, when the voltage V_{g} of the gate electrode is 0V, the current I_{d} flowing through the TFT is sufficiently low such that a leakage current in an off state is minimized.

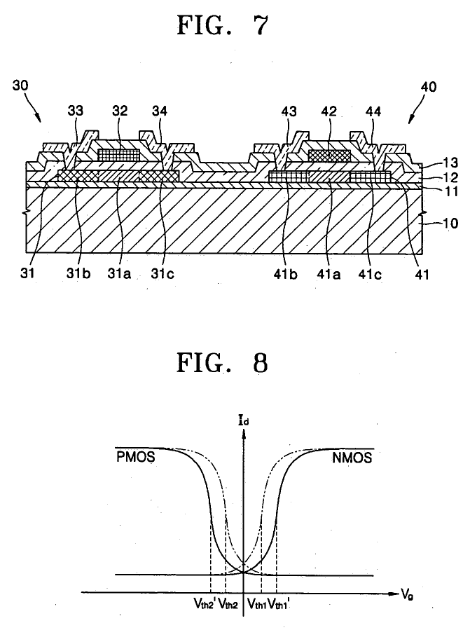

The above-described function can also be applied to a CMOS circuit shown in FIG. 7.

As shown in FIG. 7, the CMOS circuit includes an NMOS TFT 30 in which n-type impurities are doped in a source area 31b and a drain area 31c, and a PMOS TFT 40 in which p-type impurities are doped in a source area 41b and a drain area 41c.

The NMOS TFT 30 includes a first semiconductor thin film 31. The first semiconductor thin film 31 includes a channel area 31a and n-type impurity doped-source and drain areas 31b and 31c. The first semiconductor thin film 31 is covered with the gate insulating layer 12, and a first gate electrode 32 is formed on the gate insulating layer 12. Each of a first source electrode 33 and a first drain electrode 34 contacts the source and drain areas 31b and 31c of the first semiconductor thin film 31.

The PMOS TFT 40 comprises a second semiconductor thin film 41. The second semiconductor thin film 41 includes a channel area 41a and p-type impurity doped-source and drain areas 41b and 41c. The second semiconductor thin film 41 is covered with the gate insulating layer 12, and a second gate electrode 42 is formed on the gate insulating layer 12. Each of a second source electrode 43 and a second drain electrode 44 contacts the source and drain areas 41b and 41c of the second semiconductor thin film 41.

Structures of the NMOS TFT 30 and the PMOS TFT 40 are the same as described above, and thus, detailed descriptions thereof will be omitted.

In the CMOS circuit having the above structure, as described above, the threshold voltage may be modulated by varying the work function difference between the semiconductor thin film and the gate electrodes of the NMOS TFT 30 and the PMOS TFT 40. As a result, a threshold voltage margin can be modulated.

To this end, according to an embodiment of the present invention, the first gate electrode 32 of the NMOS TFT 30 and the second gate electrode 42 of the PMOS TFT 40 are formed of polysilicon. P-type impurities are doped in the first gate electrode 32, and n-type impurities are doped in the second gate electrode 42.

Consequently, as shown in FIG. 8, the threshold voltage of the NMOS TFT increases from Vₜₕ₁ to Vₜₕ₁′, and the graph of a gate voltage V_{g} versus a drain current I_{d} is shifted to the right side. In addition, the threshold voltage of the PMOS TFT increases from Vₜₕ₂ to Vₜₕ₂′, in a (−) direction and the graph of the gate voltage V_{g} versus the drain current I_{d} is shifted to the left side.

Thus, the threshold voltage margin is increased from |Vₜₕ₁−Vₜₕ₂| to |Vₜₕ₁′−Vₜₕ₂′|. When the voltage V_{g} of the gate electrode is 0V, the current I_{d} flowing through the TFT is minimized so that a leakage current in an off state is reduced.

The above-described NMOS TFT, the PMOS TFT, and the CMOS circuit may be used in manufacturing and_operating a switching device, a driving device, or a variety of kinds of drivers for a flat panel display, such as an organic electroluminescent (EL) device or a liquid crystal display (LCD).

In a TFT module configured as described above to modulate the threshold voltage. In a flat panel display having such a TFT, the following effects may be obtained. First, a threshold voltage of the TFT can be modulated by varying a difference in work functions. Second, a leakage current in an off state can be reduced. Third, power loss can be prevented. Fourth, in a CMOS circuit, the threshold voltage margin may be regulated to produce a more stable circuit.

While the present invention has been particularly shown and described with reference to exemplary embodiment thereof, it will be understood by those skilled in the art that various changes in form and details may be made therein without departing from the spirit and scope of the invention as defined by the following claims and equivalents thereof.

1. A thin film transistor, comprising:
a semiconductor thin film having a channel area and n-type or p-type impurity-doped source and drain areas;
a gate electrode formed in a position corresponding to the channel area;
a gate insulating layer, which insulates the semiconductor thin film and the gate electrode; and
source and drain electrodes, which are connected to each of the source and drain areas of the semiconductor thin film,
wherein a threshold voltage is modulated by changing a work function difference between the gate electrode and the semiconductor thin film.

2. The thin film transistor of claim 1, wherein the threshold voltage is modulated by changing the work function difference between the gate electrode and the semiconductor thin film within the range of a half of a difference of a conduction band and a balance band of the gate electrode or the semiconductor thin film.

3. The thin film transistor of claim 1, wherein the semiconductor thin film and the gate electrode are formed of polysilicon.

4. The thin film transistor of claim 3, wherein n-type or p-type impurities are doped in the gate electrode.

5. The thin film transistor of claim 4, wherein impurities different from the impurities doped in the source and drain areas are doped in the gate electrode.

6. A CMOS thin film transistor, comprising:
an NMOS thin film transistor comprising a first semiconductor thin film having a channel 3 area and n-type impurity-doped source and drain areas, a first gate electrode formed in a position 4 corresponding to the channel area of the first semiconductor thin film, a first gate insulating layer, which insulates the first semiconductor thin film and the first gate electrode, and first source and drain electrodes, which are connected to each of the first source and drain areas of the first semiconductor thin film; and
a PMOS thin film transistor comprising a second semiconductor thin film having a channel area and p-type impurity-doped source and drain areas, a second gate electrode formed in a position corresponding to the channel area of the second semiconductor thin film, a second gate insulating layer, which insulates the second semiconductor thin film and the second gate electrode, and second source and drain electrodes, which are connected to each of the second source and drain areas of the second semiconductor thin film,
wherein a threshold voltage of the NMOS thin film transistor is modulated by changing a work function difference between the first gate electrode and the first semiconductor thin film, and,
wherein a threshold voltage of the PMOS thin film transistor is modulated by changing a work function difference between the second gate electrode and the second semiconductor thin 19 film.

7. The CMOS thin film transistor of claim 6, wherein the threshold voltage of the NMOS thin film transistor is modulated by changing the work function difference between the first gate electrode and the first semiconductor thin film within the range of a half of a difference of a conduction band and a balance band of the first gate electrode or the first semiconductor thin film.

8. The CMOS thin film transistor of claim 6, wherein the threshold voltage of the PMOS thin film transistor is modulated by changing the work function difference between the second gate electrode and the second semiconductor thin film within the range of a half of a difference of a conduction band and a balance band of the second gate electrode or the second semiconductor thin film.

9. The CMOS thin film transistor of claim 6, wherein the first and second semiconductor thin films and the first and second gate electrodes are formed of polysilicon.

10. The CMOS thin film transistor of claim 9, wherein p-type impurities are doped in the first gate electrode.

11. The CMOS thin film transistor of claim 9, wherein n-type impurities are doped in the second gate electrode.

12. A flat panel display comprising the thin film transistor of claim 1.

13. A flat panel display comprising the CMOS thin film transistor of claim 6.
